(19) United States
(12) Patent Application Publication
(10) Pub. No.: US 2009/0277668 A1
(43) Pub. Date: Nov. 12, 2009

(54) Infrared emitter with flexible Circuit board

(76) Inventor: Michael Neal Kinyon, Thornton, CO (US)

Correspondence Address: MICHAEL RIES, 318 PARKER PLACE, OSWEGO, IL, 60543, US

(21) Appl. No.: 12/434,647

(22) Filed: May 3, 2009

Related U.S. Application Data
(60) Provisional application No. 61/050,988, filed on May 6, 2008.

(51) Int. Cl. H05K 1/00; H05K 3/00; B23K 31/02; B29C 65/48

(52) U.S. Cl. 174/254; 29/829; 228/164; 156/60

(57) ABSTRACT

An apparatus for coupling to an appliance includes an infrared emitter, and a flexible printed circuit board coupled to the emitter. The circuit board includes a first surface and a generally opposing second surface. At least a portion of the circuit board is flexible. The apparatus also includes a pair of circuit traces disposed on the circuit board, and an adhesive portion coupled to the first surface of the circuit board for coupling the circuit board to the appliance.

### CROSS REFERENCE TO RELATED APPLICATIONS

This application claims priority to U.S. Provisional Application 61/050,988, filed May 6, 2008, the disclosure of which is hereby incorporated by reference in its entirety.

### TECHNICAL FIELD

The disclosure relates generally to remote controls and specifically infrared (IR) emitters used in IR repeater systems.

### BACKGROUND

Many appliances such as televisions, stereos, cable control boxes, satellite dish control units, and digital video disk (DVD) player/recorders include remote control hand held devices for controlling the function of the appliance without physical contact with the appliance. Many, if not all, of these remote control devices include infrared emitters that send a signal to an infrared receiver positioned on the corresponding appliance. Each infrared receiver is typically positioned on a visible portion of each appliance since the operation of the each remote control device requires that the emitter has a line-of-sight communication with its corresponding receiver. When components are located in an inaccessible location, such as behind a wooden cabinet door, the dedicated remote control may be incapable of sending a signal to the corresponding infrared receiver. Often, a user will open the cabinet door during use of the appliance, although this involves the existence of an open cabinet door that may interfere with traffic and a reduction in the uncluttered appearance provided when the cabinet door is closed and the appliances are out of view.

The inconvenience of remotely controlling appliances that are positioned in inaccessible locations has led to the development of remote control infrared repeater systems. Many of these remote control infrared repeater systems include at least one infrared receiver a single infrared repeater receiver that is capable of receiving signals from multiple hand held remote controls for controlling the function of multiple appliances. The repeater receiver sends a signal to a distribution block or system control box and then to the appropriate appliance for control thereof similar to the control function of the appliances dedicated hand held remote control device. To send this signal to the appropriate appliance, many repeater systems include multiple infrared repeater emitters where each repeater emitter is positioned adjacent and in communication with an infrared receiver of each appliance. Necessarily, these repeater emitters are positioned on the visible and accessible portions of each appliance. Often, each infrared repeater emitter is secured to the appliance and each infrared emitter includes a pair of loose connecting wires extending therefrom.

Many of these repeater emitters and wires are visibly distracting and vulnerable to inadvertent contact by a user due to the position of the repeater emitters. Undesirably, these wires extending from the infrared emitters may be disconnected from the repeater emitter as the device is repositioned or as normal use of the appliances results in a user inadvertently pulling the wires, or the emitters may be easily dislodged from the desired mounting location due to a small area of adhesive tape on just the emitter head, resulting in a loss of communication. This disconnection may result in breaking a connection that is not easily reconnected by the user, resulting in disposal of the emitter and the purchase of an additional emitter. If the disconnection is partial and/or sporadic, the emitter may function properly at times and not function properly at other times, resulting in an unreliable repeater system functionality.

### BRIEF DESCRIPTION OF THE DRAWINGS

Referring now to the drawings, illustrative embodiments are shown in detail. Although the drawings represent some embodiments, the drawings are not necessarily to scale and certain features may be exaggerated, removed, or partially sectioned to better illustrate and explain the present invention. Further, the embodiments set forth herein are exemplary and are not intended to be exhaustive or otherwise limit or restrict the claims to the precise forms and configurations shown in the drawings and disclosed in the following detailed description. Section lines and/or surface graphics may be omitted for clarity of illustration.

FIG. 1 is a perspective view of an appliance.

FIG. 2 is a perspective view of an appliance with an IR repeater system, according to an embodiment

FIG. 3 is side view of an IR emitter of FIG. 2, illustrated in a contoured configuration.

FIG. 4 is front view of the IR emitter of FIG. 3, illustrated in a non-contoured configuration with a housing removed for clarity of illustration.

FIG. 5 is rear view of the IR emitter of FIG. 3, illustrated in a non-contoured configuration.

FIG. 6 is an enlarged view of portion 6 of FIG. 3.

FIG. 7 is front view of another embodiment of an IR emitter illustrated in a non-contoured configuration with housings removed for clarity of illustration.

FIG. 8 is side view of an IR emitter of FIG. 7, illustrated in a non-contoured configuration.

FIG. 9 is an enlarged view of portion 9 of FIG. 8.

FIG. 10 is a side view of a cap, according to an embodiment with portions not illustrated in phantom for clarity of illustration.

FIG. 11 is a top view of the cap of FIG. 10, with components removed for clarity of illustration.

FIG. 12 is an exploded view of the cap of FIG. 10.

FIG. 13 is an exploded view taken generally along line 13-13 of FIG. 10, with components removed for clarity of illustration.

### DETAILED DESCRIPTION OF THE DRAWINGS

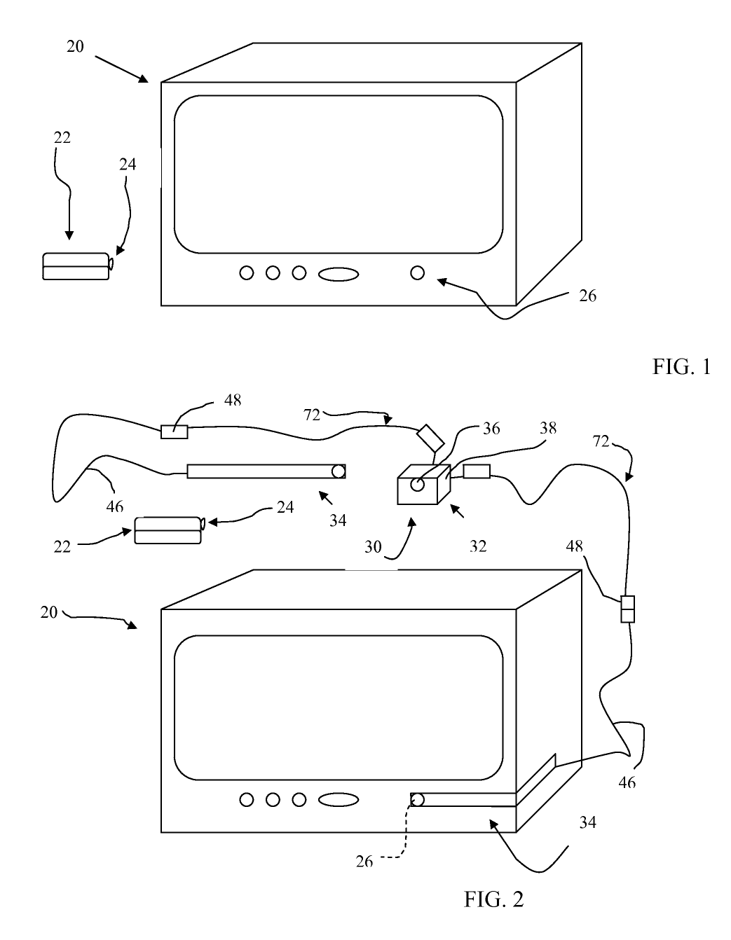

FIG. 1 illustrates an appliance 20. The appliance 20 includes an IR remote 22 having an IR emitter 24, and an IR receiver 26. The infrared remote 22 selectively sends a signal from the IR emitter 24 to the IR receiver 26 for functional control of the appliance 20.

FIG. 2 illustrates one of a plurality of appliances 20 operably connected to an IR repeater system 30. The IR repeater system 30 includes a central control assembly 32, and a plurality of IR repeater emitter assemblies 34. The control assembly 32 includes an IR repeater receiver 36 and a control system 38 capable of generating a copy of an IR signal received by the IR repeater receiver 36 and sending the generated signal to at least one of the IR repeater emitter assemblies 34. While the IR repeater system 30 is illustrated schematically to control an appliance such as a television, it is understood that the system 30 may control various appliances that receive IR signals.

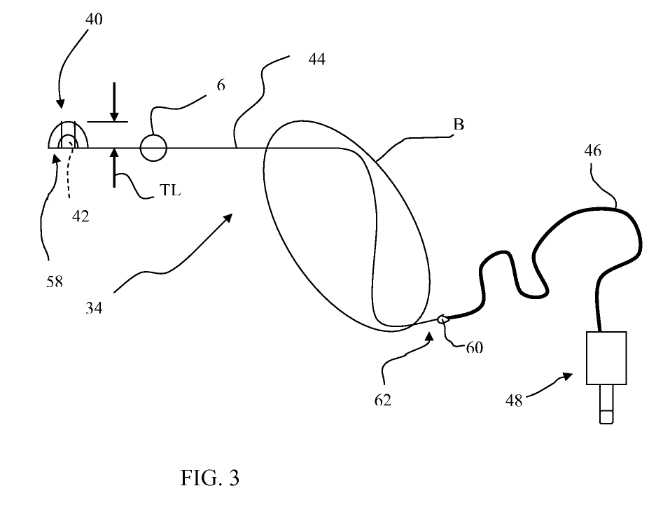

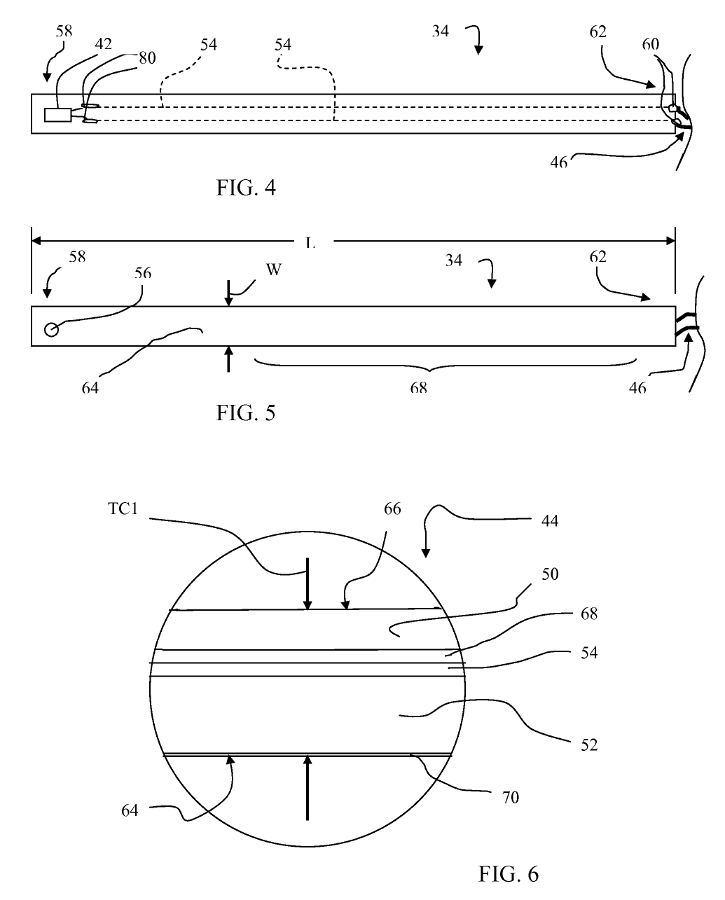

FIG. 3 illustrates an embodiment of an IR repeater emitter assembly 34 to include an IR repeater emitter housing 40 with an IR light emitting diode (LED) emitter 42 positioned therein, a flexible circuit board 44, a wire harness 46, and a male mono plug 48. As best seen in at least one of FIGS. 4-7, the circuit board 44 includes an overlay portion 50, a substrate 52, a pair of circuit traces 54, an aperture 56 located adjacent a first end 58, a pair of connection points 60 located at a second end 62, a first surface 64, and a second surface 66. At least a portion, illustrated generally within the oval region B, of the circuit board 44 is flexible, although the entire circuit board 44 may be flexible.

In the embodiment illustrated, the circuit board 44 includes a coating 68 for protecting the circuit traces 54. The coating 68 covers the circuit traces 54 and may cover the entire substrate 52. The coating 68 may be a resin or other suitable material. The circuit board 44 may also include an adhesive portion 70 (FIG. 6) coupled to the first surface 64 for adhering or otherwise coupling the circuit board 44 to the appliance 20.

The IR repeater system 30 may also include a plurality of extension cables 72 to permit the control system 38 to be located a greater distance from the appliances 20. In the embodiment illustrated, the extension cables 72 are six feet in length and contain a female 3.5 mm mono (2-conductor) female plug at one end and a male 3.5 mm mono (2-conductor) female plug at the other end. In the embodiment illustrated, the wire harness 46 includes two wires, one for connection to each circuit trace 54, although any suitable number of wires may be included.

As best seen in FIG. 3, the thickness of the IR repeater emitter housing 40 and the circuit board 44 is illustrated as TL (FIG. 3). The IR LED emitter 42 is coupled to the circuit board 44 with a pair of solder contacts 80 that electrically connect the IR LED emitter 42 to the circuit traces 54. As illustrated, the solder contacts 80 are enclosed in the housing 40. In one embodiment, the thickness TL is about 3 millimeters (0.125 inch). The IR repeater emitter housing 40 may be a semi-translucent epoxy or plastic resin that is applied in liquid form to the LED emitter 42 and circuit board 44, or may be a plastic or other suitable housing that is coupled to the circuit board as a solid. Therefore, the housing 40 is adjacent, or near, the IR LED emitter 42 and may retain the IR LED emitter 42 relative to the circuit board 44. Further, the housing 40 may be red, or other desirable coloring.

As best seen in FIG. 6, the distance between the first surface 64 and the second surface 66 defines the maximum thickness TC1 of the circuit board 44. In one embodiment, the maximum thickness of the flexible portion B of the circuit board 44 is about 1.0 millimeter (about 0.04 inch) or less. In other embodiments, the maximum thickness of the circuit board 44 may be about 0.1 mm (0.004 inch), although other suitable thicknesses may be used. Further, the circuit board 44 may be replaced by a flat wire tape.

The adhesive portion 70 may directly attach the first surface 64 of the substrate 52 of the circuit board 44 to an outer surface of the appliance 20. The adhesive portion 70 may include double sided tape, or an adhesive with a release paper that may be removed by a user prior to coupling the IR repeater emitter assembly 34 to the appliance 20, or any suitable substance for coupling the IR repeater emitter assembly 34 to the appliance 20, a door, or a shelf. Further, the adhesive portion 70 may cover all or portions of the first surface 64, as desired.

In one embodiment the flexible printed circuit board substrate 52 is a polyimide substrate, although other suitable materials may be used. Further, the circuit board 44 may be produced in various suitable lengths, depending upon the dimensions of the appliance. The circuit traces 54 may be embedded in the substrate 52, or may be interposed between the overlay portion 50 and the substrate 52. Further, the overlay portion 50 may be coupled to the substrate 52 by any suitable means. In one embodiment, the overlay portion 50 protects the circuit traces 54 from damage or short circuiting. Additionally, the circuit board may have a width W of about 3 mm (0.125 inch) and a length L of about 12 inches, although other suitable dimensions may be used.

The overlay portion 50 may be colored to complement the coloring of the appliance 20, as desired. In one embodiment, the overlay portion 50 is painted to complement the color of the appliance 20. Therefore, the overlay portion 50 may selectively reduce the visual detection of the IR repeater emitter assembly 34 when coupled to the appliance 20. Further, the overlay portion 50 may be omitted.

In one embodiment, the control system 38 includes a distribution hub for transmitting signals from multiple infrared transmitters, such as the infrared remote 22. The control system 38 may also include an outside power source. Other control systems may include computerized control systems, and/or radio frequency (RF) control systems that convert an RF signal to an IR signal.

While the illustrative embodiment includes two IR repeater emitter assemblies 34, any suitable number of IR repeater emitter assemblies 34 may be used, as desired. The IR LED emitter 42 may be any suitable emitter, including an organic light emitting diode. The IR LED may emit visible light as well as the primary infrared signal.

During installation of an IR repeater emitter assembly 34, the adhesive portion 70 is prepared, such as by removing any release paper, and the aperture 56 is positioned over the IR receiver 26 of the appliance 20. The assembly 34 is then brought into contact with the appliance 20 and the circuit board 44 is contoured to an outside surface portion of the appliance 20 (FIG. 2). In this manner, the IR repeater emitter assembly 34 is more resistant to inadvertent disconnection of the control system 38 to the IR LED emitter 42, when compared to an emitter system including an emitter that may be secured to an appliance where the emitter includes wire leads extending directly from an IR LED emitter.

When the control system 38 sends a signal to the emitter 42, the emitter will emit an IR signal that passes through the aperture 56 and is received by the IR receiver 26. As illustrated in FIG. 2, the circuit board 44 may extend along the front of the appliance 20 and along a portion of a side of the appliance 20.

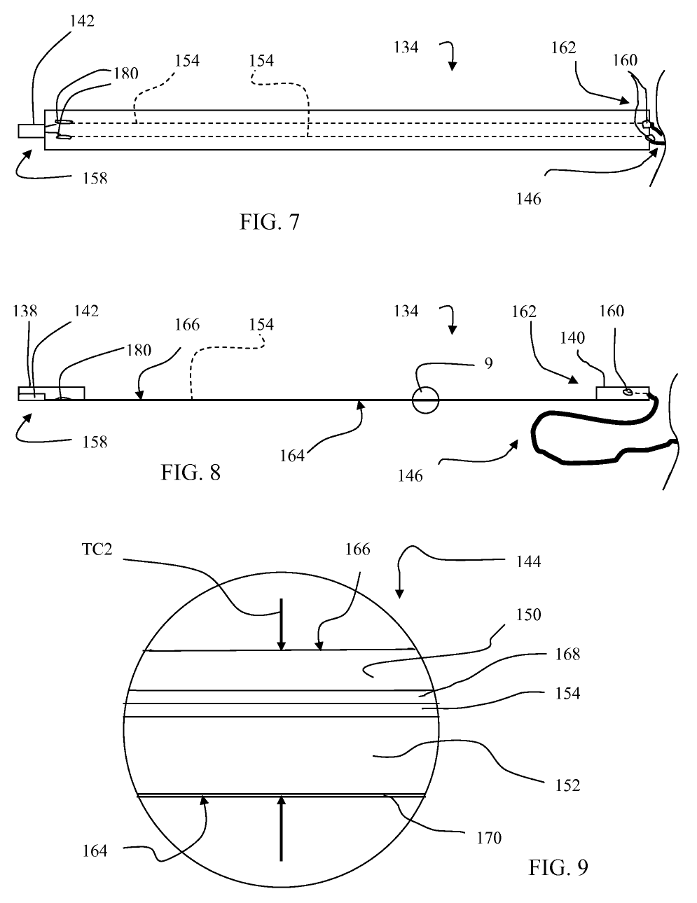

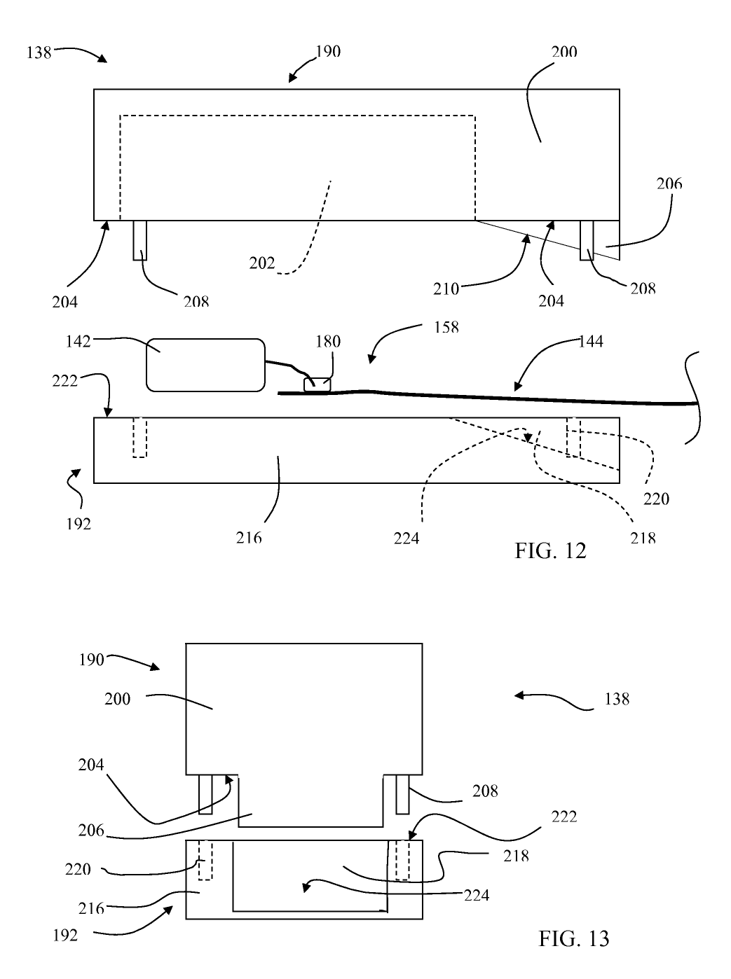

FIGS. 7-13 illustrate another embodiment of the IR repeater emitter assembly 34 as an IR repeater emitter assembly 134. The IR repeater emitter assembly 134 includes an IR repeater emitter cap 138, and an overlay cap 140 with an IR light emitting diode (LED) emitter 142 positioned therein, a flexible circuit board 144, a wire harness 146, and a male mono plug (not shown). The circuit board 144 includes an overlay portion 150, a substrate 152, a pair of circuit traces 154, a first end 158, a pair of connection points 160 located at a second end 162, a first surface 164, and a second surface 166. At least a portion, illustrated generally within the oval region B, of the circuit board 144 is flexible, although the entire circuit board 144 may be flexible.

In the embodiment illustrated, the circuit board 144 includes a coating 168 for protecting the circuit traces 154. The coating 168 covers the circuit traces 154 and may cover the entire substrate 152. The coating 168 may be a resin or other suitable material. The circuit board 144 may also include an adhesive portion 170 (FIG. 9) coupled to the first surface 164 for adhering or otherwise coupling the circuit board 144 to the appliance 20.

The cap 138 may be a plastic (such as polycarbonate) that covers the LED emitter 42 and the solder contacts 180. The cap 138 may be a plastic or may be made of similar material as the overlay portions 50, 150. In the embodiment illustrated, the cap 138 is colored to match the overlay portion 150, although the cap 138 may be any suitable color or texture.

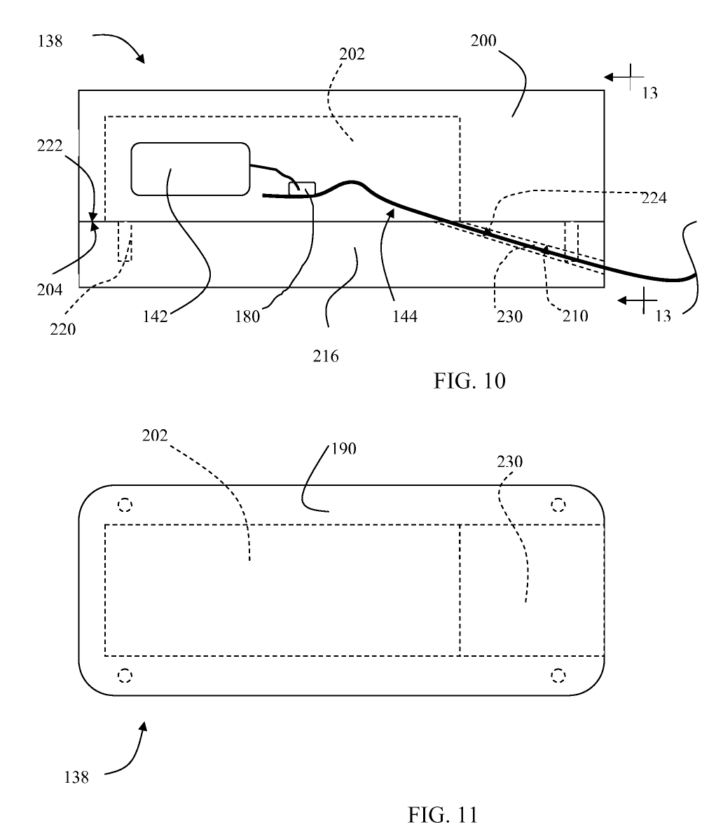

The IR LED emitter 142 is coupled to the circuit board 144 with a pair of solder contacts 180 that electrically connect the IR LED emitter 142 to the circuit traces 154. In the embodiment illustrated, the cap 138 encases the solder contacts 180 and at least a portion of the IR LED emitter 142, as discussed in greater detail relating to FIGS. 10-13.

The cap 140 may be a “stress relief” for the connection of the wire harness 146 to the circuit board 144 at the connection points 160 by reinforcing this connection. In the embodiment illustrated, the connection points 160 are soldered contacts, although other suitable connector means, such as a mechanically clamped connection, may be used. Further, the cap 140 may be a mechanical clamp that electrically connects the wire harness 146 to the circuit board 144 at the connection points 160.

FIGS. 10-13 illustrate the IR repeater emitter cap 138 in greater detail. The cap 138 includes a first cap portion 190 and a second cap portion 192. The first cap portion 190 includes a first body 200 having a cavity 202, a lower surface 204 having a first portion 206 and a plurality of alignment pins 208 extending therefrom. The first portion 206 includes a first portion surface 210.

The second cap portion 192 includes a second body 216, having a second channel 218 and a plurality of alignment apertures 220 formed therein, and an upper surface 222. The second channel 218 is at least partially defined by a second portion surface 224. To assemble the cap 138, the emitter 142 and the first end 158 of the circuit board 144 are interposed at least partially within the cavity 202 and a portion of the circuit board 144 adjacent the first end 158 is interposed within the second channel 218. The first cap portion 190 is brought into contact with the second cap portion 192 such that the alignment pins 208 guide within the alignment apertures 220 and the lower surface 204 contacts the upper surface 222. In the embodiment illustrated, the resulting clearance between the first portion surface 210 and the second portion surface 224 forms a circuit board path 230 such that the adjacent portion of the circuit board 144 is bindingly engaged therebetween to retain the adjacent portion of the circuit board 144 from moving relative to the cap 138. Similarly, the cap 140 may bindingly engage both the wire harness 146 and the circuit board 144 to retain the circuit board 144 from moving relative to the cap 140. Additionally, the cavity 202 may be at least partially sealed, thereby protecting the emitter 142 and the connection between the emitter 142 and the circuit board 144. An adhesive may be used between the surfaces 204, 222 and/or 210, 224 to retain the cap 138 and the circuit board 144 generally in the position illustrated in FIG. 10.

While the first portion surface 210 and the second portion surface 224 are illustrated as generally planar, these surfaces may be contoured to provide an increased grip on the circuit board 144 and/or for providing a tortuous path for the circuit board 144 to navigate. Additionally, the surfaces 204, 222 are illustrated as generally planar. As will be appreciated, shaping the surfaces 204, 222 and/or 210, 224 in a non-planar configuration may reduce or eliminate the need for the alignment pins 208 and the alignment apertures 220.

The cap 138 and the cap 140 may include an adhesive or double-sided tape for coupling the caps 138, 140 to an appliance, such as the appliance 20. The first cap portion 190 and the second cap portion 192 may be a tinted or colored semi-translucent plastic so as to allow the passage of infrared and visible light. The cap 140 may be constructed of the same material as a portion of the wire harness 146, or any suitable material, such as the same material as the cap 138.

FIG. 10 does not illustrate the circuit board 144 and emitter 142 in phantom for clarity of illustration. Further, the circuit board 144 is illustrated within the path 230 to distinguish between surfaces 210, 224, and the circuit board 144, although in the embodiment discussed, at least a portion of the circuit board 144 contacts at least a portion of the surfaces 210, 224.

Further, the second end 162 of the emitter assembly 134 may include a cap 140 to protect the connection of the circuit board 44 to the wire harness 46. The first end 58 of the emitter assembly 34 may include a cap 138 where the signal emitted from the emitter 42 will pass through the aperture 56 and the second cap portion 192.

In the embodiment of FIGS. 7-13, the emitter 142 may emit an IR light in multiple directions with at least a portion of the IR signal reaching the IR receiver 26 of the appliance 20. The thickness TC2 (FIG. 9) of the circuit board 144 is similar to the thickness TC1. Additionally, the circuit board 144 may be flexible in similar fashion as the circuit board 44 is flexible.

To attach the IR repeater emitter assembly 134 to an appliance, such as an appliance 20, the infrared emitter 142 is positioned so as to be in selective communication with the infrared receiver 26 of the appliance 20. That is, the infrared emitter 142 is positioned such that the infrared receiver 26 may receive an IR signal sent from the infrared emitter 142. Then, the circuit board 144 is contoured to the appliance 20, as desired to mold the circuit board 144 to the appliance 20 and ensure that the adhesive portion 170 is sufficiently bonded to the appliance 20 and the circuit board 144 to retain the circuit board 144 in the deformed configuration.

The contouring of the circuit board 44, 144 to an appliance will ensure that the adhesive portion 70, 170 is adequately applied to the outer surface of the appliance and may maintain the circuit board 44, 144 in a deformed configuration as the circuit board 44, 144 curves to fit the outer surface, thus improving the appearance and reducing inadvertent snagging of the connectors between the emitter 42, 142 and the control 38.

As used herein, the term “flexible circuit board” includes circuit boards with a polyimide or plastic substrate with sufficient thinness to permit the circuit board to be flexed, as desired. Also, as used herein, the term ‘contour’ includes to shape so as to fit a surface.

Although the steps of the method of assembling the assembly 34 and operating the system 30 may be listed in a preferred order, the steps may be performed in differing orders or combined such that one operation may perform multiple steps. Furthermore, a step or steps may be initiated before another step or steps are completed, or a step or steps may be initiated and completed after initiation and before completion of (during the performance of) other steps.

The preceding description has been presented only to illustrate and describe exemplary embodiments of the methods and systems of the present invention. It is not intended to be exhaustive or to limit the invention to any precise form disclosed. It will be understood by those skilled in the art that various changes may be made and equivalents may be substituted for elements thereof without departing from the scope of the invention. In addition, many modifications may be made to adapt a particular situation or material to the teachings of the invention without departing from the essential scope. Therefore, it is intended that the invention not be limited to the particular embodiment disclosed as the best mode contemplated for carrying out this invention, but that the invention will include all embodiments falling within the scope of the claims. The invention may be practiced otherwise than is specifically explained and illustrated without departing from its spirit or scope. The scope of the invention is limited solely by the following claims.

What is claimed is:

1. An apparatus for coupling to an appliance comprising:
an infrared emitter;
a flexible printed circuit board coupled to the emitter, wherein the circuit board includes a first surface and a generally opposing second surface, and wherein at least a portion of the circuit board is flexible;
a pair of circuit traces disposed on the circuit board; and
an adhesive portion coupled to the first surface of the circuit board for coupling the circuit board to the appliance.

2. The apparatus of claim 1, wherein the emitter is an infrared light emitting diode.

3. The apparatus of claim 1, wherein the emitter is an organic infrared light emitting diode.

4. The apparatus of claim 1, wherein the adhesive portion directly attaches the first surface of the circuit board to an outer surface of the appliance.

5. The apparatus of claim 1, further comprising an overlay portion disposed on at least a portion of the circuit board, wherein the overlay portion will selectively reduce the visual detection of the apparatus when coupled to the appliance.

6. The apparatus of claim 1, wherein at least a portion of the circuit board is contoured to an outer surface portion of the appliance.

7. The apparatus of claim 1, wherein flexible printed circuit board includes a substrate that includes a polyimide.

8. The apparatus of claim 1, wherein the circuit board includes an aperture and the emitter is coupled to the circuit board to direct a signal through the aperture.

9. The apparatus of claim 1, wherein the distance between the first surface and the second surface defines the maximum thickness of the circuit board and the maximum thickness of the flexible portion of the circuit board is less than about 1.0 millimeter.

10. The apparatus of claim 9, wherein the maximum thickness of the flexible portion of the circuit board is less than about 0.5 millimeter.

11. A method comprising:
forming at least one circuit trace on a circuit board, wherein the circuit trace is disposed on at least a flexible portion of the circuit board;
coupling an infrared emitter to a portion of the circuit board; and
contouring at least a portion of the circuit board to an outer surface of an appliance.

12. The method of claim 11, further comprising positioning the infrared emitter in selective communication with an infrared receiver of the appliance.

13. The method of claim 11, further comprising forming an aperture within the circuit board.

14. The method of claim 13, further comprising directing a signal from the infrared emitter through the aperture.

15. The method of claim 11, wherein coupling the infrared emitter includes soldering the infrared emitter to the circuit board.

16. The method of claim 11, further comprising transferring a signal from an infrared repeater system to the appliance.

17. The method of claim 11, further comprising coupling at least a portion of the circuit board to the appliance.

18. The method of claim 11, further comprising forming a housing adjacent the infrared emitter and a portion of the circuit board for retaining the infrared emitter relative to the circuit board.

19. The method of claim 11, further comprising coupling an overlay portion to the circuit board, wherein the overlay portion protects the circuit trace.

20. The method of claim 11, further comprising applying an adhesive to the circuit board.
